(19) United States
(12) Patent Application Publication
(10) Pub. No.: US 2006/0192545 A1
(43) Pub. Date: Aug. 31, 2006

(54) Voltage detection pole

(75) Inventor: Antonios L. Karagiannis, Raleigh, NC (US)

Correspondence Address: WILLIAM L. LONDON, 3010 LEE AVENUE, P.O. BOX 152, SANFORD, NC, 27330, US

(73) Assignees: Static Control Components, Inc., Sanford, NC (US); Santronics, Inc.

(21) Appl. No.: 11/068,079

(22) Filed: Feb. 28, 2005

(51) Int. Cl. G01R 31/02

(52) U.S. Cl. 324/72.5

(57) ABSTRACT

An elongate probe of at least 2 feet in length for alerting a user to the presence of electrical energy includes an antenna to sense radiated electrical energy and an indicator to alert a user when activated. Circuitry determines when the sensed electrical energy meets a user adjustable threshold and activates the indicator when the sensed electrical energy meets the user adjustable threshold. An adjustor allows for selecting the user adjustable threshold.

### BACKGROUND

The present invention generally relates to the field of test equipment, and more particularly to an elongate voltage detection pole to sense the presence of an alternating current (AC) signal voltage at a distance.

Due to problems with maintenance, corrosion or the poaching of electricity supplied by a public utility company, exposed electrical wire may come in contact with conducting surfaces, such as metal utility poles, manhole covers or puddles of water, resulting in electrified “hot spots” in public areas. These hotspots can be harmful, and even fatal, if contacted by a passerby. Additionally, the area of these hotspots can be very irregular and difficult to detect.

Thus, there is a need for a system and techniques for sensing an electrified metal utility pole or other structure to allow for proper repair before someone is injured. Additionally, there is a need for a system and techniques for allows an alternating current to be sensed at a distance before an individual moves near the electrified element. Moreover, there is a need for a system and techniques which allows a user to adjust the sensitivity of sensing system by having a high sensitivity when searching at a distance and then reducing the sensitivity when moving closer to the electrified structure.

Additionally, there is a need for a voltage sensing system which is mounted to a utility pole or other structure and provides an indication when the utility pole is electrified.

### SUMMARY

In one aspect of the present invention, an elongate probe of at least two feet in length for alerting a user to the presence of electrical energy includes an antenna to sense radiated electrical energy and an indicator to alert a user when activated. Circuitry determines when the sensed electrical energy meets a user adjustable threshold and activates the indicator when the sensed electrical energy meets the user adjustable threshold. An adjustor allows for selecting the user adjustable threshold.

A more complete understanding of the present invention, as well as further features and advantages of the invention, will be apparent from the following detailed description and the accompanying drawings.

### BRIEF DESCRIPTION OF THE DRAWINGS

FIG. 1 shows a perspective view of a voltage detection pole in accordance with the present invention;

FIG. 2 shows a cross sectional view of a voltage detection pole in accordance with the present invention;

FIGS. 3A and 3B show a schematic diagram of circuitry suitable for use in a voltage detection pole in accordance with the present invention;

FIG. 4 shows a schematic diagram of circuitry suitable for use in a voltage detection pole in conjunction with the present invention;

FIG. 5 shows a utility pole mounted system for detecting alternating current in accordance with the present invention; and

FIG. 6 shows of block diagram of the system of FIG. 5 in accordance with the present invention.

### DETAILED DESCRIPTION

The following detailed description of preferred embodiments refers to the accompanying drawings which illustrate specific embodiments of the invention. In the discussion that follows, specific systems and techniques for sensing alternating current are disclosed. Other embodiments having different structures and operations for the manufacture of other systems do not depart from the scope of the present invention.

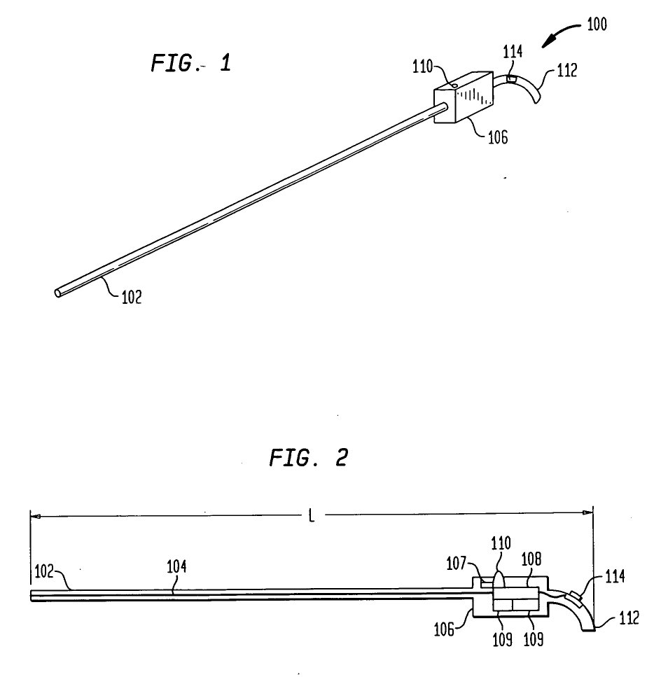

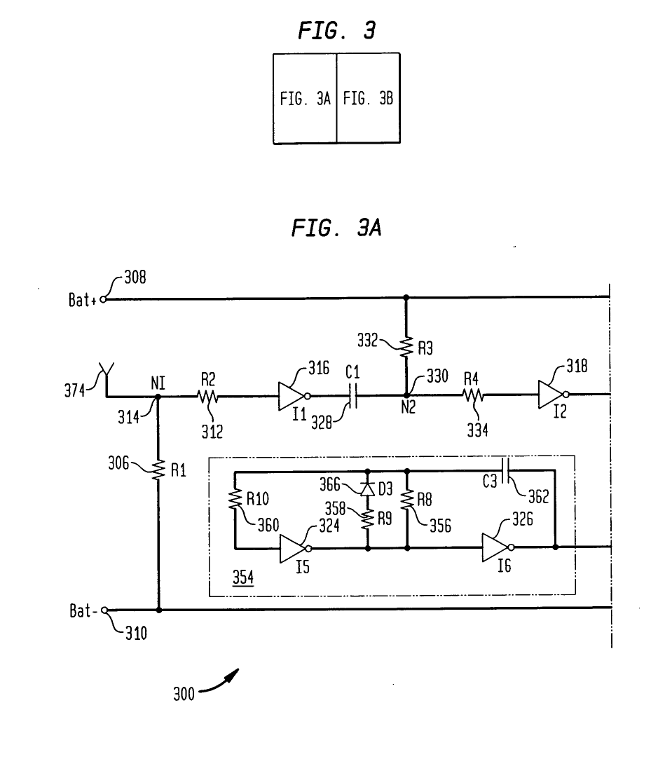

FIGS. 1 and 2 show respectively a perspective view and a cross sectional view of a voltage detection pole 100 in accordance with the present invention. The voltage detection pole 100 comprises an elongate shaft 102 enclosing an antenna 104. The antenna 104 operates as a sensing element for sensing changes in an electromagnetic field near the antenna 104. In a preferred embodiment, the elongate shaft 102 is a non-conductive material, such as polyvinyl chloride (PVC), for example. The elongate shaft 102 may be telescoping or retractable to allow for easy storage and deployment of the antenna 104. The elongate probe 100 has a length L, as shown in FIG. 2.

A housing portion 106 affixed to the elongate shaft 102 houses processing electronics 108 connected to the antenna 104 for processing the signal received by the antenna 104 and determining if the antenna 104 is near a conductor conducting an AC signal having a sensed amplitude above a user selectable threshold, as described in greater detail below. The housing portion 106 may also comprise an audible buzzer 107 and a visual indicator 110 controlled by the processing electronics 108 for communicating the presence of a sensed alternating current to a user. Batteries 109 may suitably power the processing electronics. A handle 112, for holding and manipulating the voltage detection pole 100, is also attached to the housing portion 106. The handle 112 holds an adjustment element 114 connected to the processing electronics 108 for controlling the user selectable threshold. Alternately, the housing portion 106 may hold the adjustment element 114.

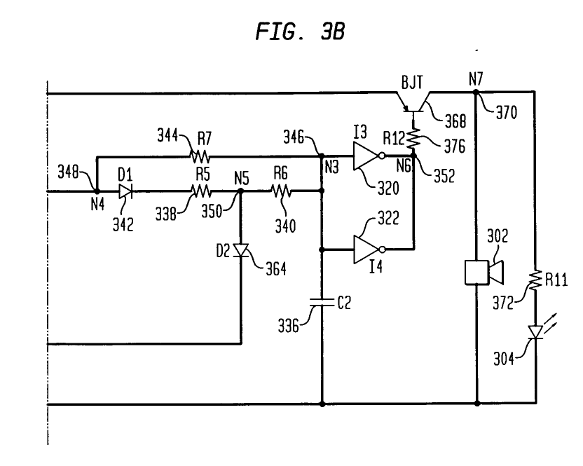

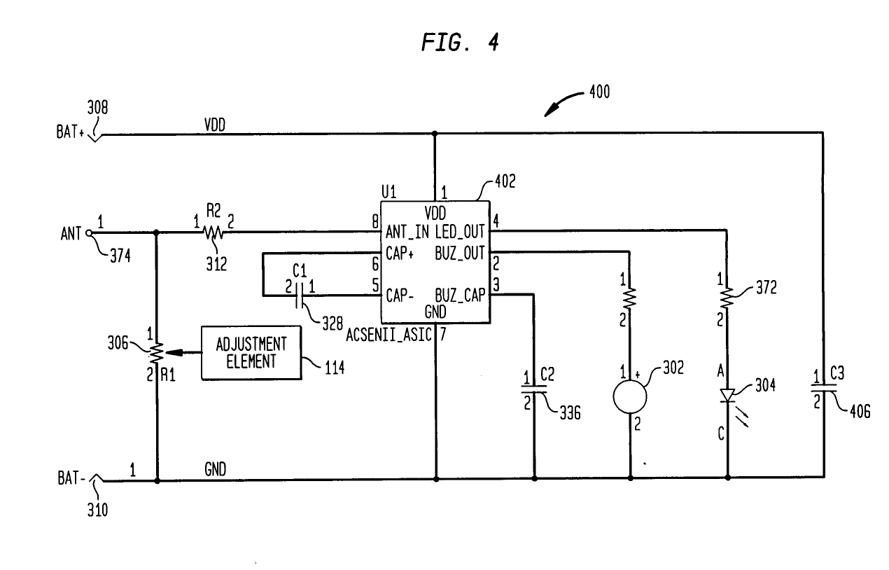

FIGS. 3A and 3B show a schematic diagram of circuitry 300 suitable for use as the processing electronics 108 in accordance with the present invention. Further general details of the operation of circuitry 300 are provided in U.S. Pat. No. 6,828,767, which is incorporated by reference herein in its entirety. FIG. 4 shows a schematic diagram of an alternate embodiment of circuitry 400 suitable for use as the processing electronics 108 in accordance with the present invention. The circuitry 400 is similar to the circuitry 400 and corresponding elements have been labeled with common element numbers. In the circuitry 400, a majority of the discrete elements of the circuit 300 are implemented in an application specific integrated circuit (ASIC) 402 of the circuitry 400. A 10 microfarad decoupling capacitor 406 may be suitably connected between the positive battery terminal 308 and the negative battery terminal 310. The resistor 312 (R2) may be 120 Mohms.

The sensitivity of the voltage detection pole 100 is the voltage threshold level at which the voltage detection pole 100 will provide an indication to the user of sensed AC voltage. As described in U.S. Pat. No. 6,828,767, this sensitivity is determined by the value of the resistor 306. In order to allow the user of the voltage detection pole 100 to select the voltage threshold level, the resistor 306 may suitably comprise a variable resistor controlled by adjustment element 114, allowing a user to dynamically control the sensitivity of the voltage detection pole 100 by turning a dial. Alternately, the adjustment element 114 may comprise a switch which switches additional resistive elements into or out of a parallel configuration with the resistor 306 to raise or lower the voltage threshold level. By allowing the value to the resistor 306 to be increased to 1.5 Gohms, the voltage threshold level may be lowered to 2 volts RMS or lower. By decreasing the value of the resistor 306 to 150 Mohms, the voltage threshold level may be raised to 16 volts RMS.

In order to allow a user to safely determine if an AC voltage is present in an area, the voltage detection pole 100 is preferably at least 2 feet in length, more preferably at least 2.5 feet in length, and in particular at least 3 feet in length, to allow the user detect the AC voltage from a distance without approaching the voltage source too closely. A typical prior art device that has a short length may put the user in danger by forcing the user to approach the AC voltage and risk electric shock. The length of the voltage detection pole 100, and thus the extension of the antenna 104 from the user, allows the user to quickly move the tip of the voltage detection pole 100 around an area with the voltage threshold level set to a low level and determine if there is any AC voltage present. Thus, in addition to keeping the user further away from dangerous voltages, the length of at least 2 feet allows for more efficient testing of an area by increasing the reach of the test and allowing the end of the voltage detection pole 100 to be quickly moved about. Additionally, the length of at least 2 feet allows the user to test areas or structures that are high off the ground. Moreover, the length of at least 2 feet allows a user to extend the voltage detection pole through an open window of a vehicle to test objects near the vehicle.

If AC voltage is detected, the user may increase the voltage threshold level as needed while continuing the search to further narrow the area having the AC voltage. In other words, a user may adjust the sensitivity of voltage detection pole 100 by controlling the adjustment element 114 to select a high sensitivity when searching at a distance and then reducing the sensitivity when moving closer to the electrified structure to further narrow the search to the specific hot spot.

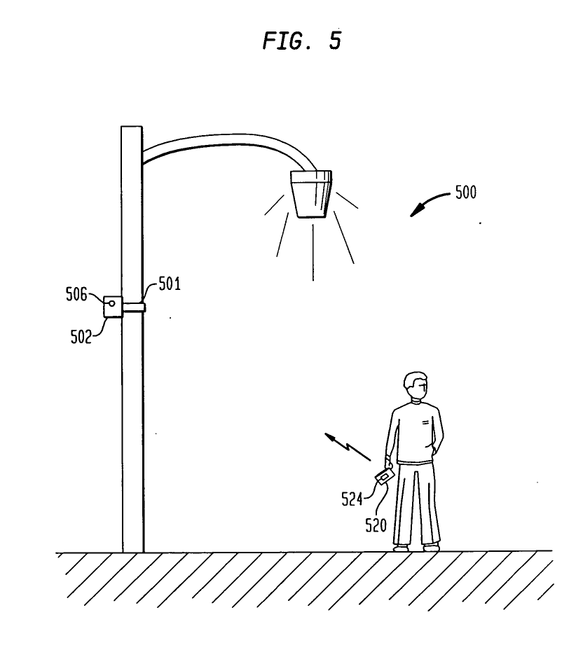

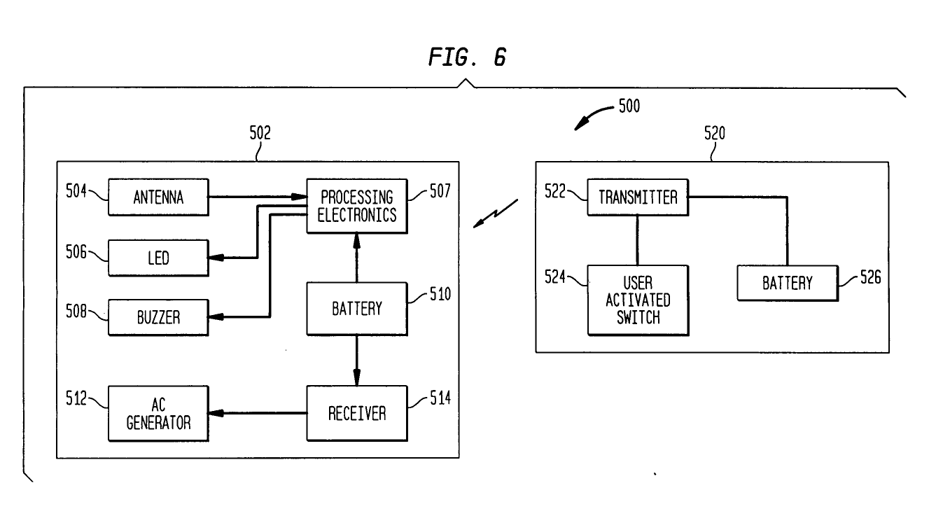

In another aspect of the present invention, a voltage sensing system is adapted for attachment a utility pole or other structure and provides an indication when the utility pole is electrified. FIG. 5 shows a utility pole mounted system 500 for detecting alternating current in accordance with the present invention. FIG. 6 shows a block diagram of the system 500 in accordance with the present invention. As seen in FIG. 5, a utility pole mounted sensor 502 may be mounted to a metal utility or light pole by steel bands 501. The sensor 502 may comprise an antenna 504 and processing electronics 507, which operates in similar fashion to the processing electronics described above, with the voltage threshold set to a predetermined level. A battery 510 suitable for use in low temperature environments may be used to power the pole mounted sensor 502. Alternatively, other power sources such as solar power, AC power and the like may be utilized. The sensor 502 includes an LED 506 and a buzzer 508 controlled by the processing electronics for alerting someone near the pole that the pole is carrying a potentially harmful alternating current.

The pole mounted sensor 502 may also include an AC generator 512 for testing the sensor 502. The AC generator 512 may suitably generate an AC signal of 2-30 volts RMS. When the AC generator 512 is operating and producing a signal, the processing electronics 507 will sense a corresponding signal received by the antenna 504 and cause the LED 506 and buzzer 508 to activate. The AC generator may be activated remotely, utilizing a radio frequency (RF) or infrared (IR) signal, by someone holding an testing unit 520 which communicates with the pole mounted sensor 502. The testing unit 520 comprises a transmitter 522 controlled by a user activated switch 524 and powered by a battery 526. When a user activates the switch 524, the transmitter 522 sends a signal to the receiver 514 of the sensor 502, which in turn, activates the AC generator 512. Thus, someone responsible for verifying that no hot spots exist may first view the pole mounted sensor 502 to ensure that the sensor 502 is not reporting an electrified pole and the use the testing unit 520 to test the pole mounted sensor 502 to ensure proper operation. Optionally, the AC generator 512 may be packaged separately from the sensor 502.

Although specific embodiments have been illustrated and described herein, those of ordinary skill in the art appreciate that any arrangement which is calculated to achieve the same purpose may be substituted for the specific embodiments shown and that the invention has other applications in other environments. This application is intended to cover any adaptations or variations of the present invention. The following claims are in no way intended to limit the scope of the invention to the specific embodiments described herein.

What is claimed is:

1. An elongate probe for alerting a user to the presence of electrical energy comprising:
an antenna to sense radiated electrical energy;
an indicator to alert a user when activated;
circuitry for determining when the sensed electrical energy meets a user adjustable threshold and activating the indicator when the sensed electrical energy meets the user adjustable threshold; and
an adjustor for selecting the user adjustable threshold,
wherein the elongate probe has a length of at least 2 feet.

2. The elongate probe of claim 1 wherein the elongate probe comprises an elongate body holding the antenna.

3. The elongate probe of claim 2 wherein the length of the elongate body is adjustable.

4. The elongate probe of claim 2 wherein the antenna extends substantially along the length of the elongate body.

5. The elongate probe of claim 1 wherein the elongate probe has a length of at least 2.5 feet.

6. The elongate probe of claim 5 wherein the elongate probe has a length of at least 3 feet.

7. A method for detecting a source of electrical energy in an area comprising:
providing an elongate probe for alerting a user to the presence of electrical energy comprising an antenna to sense radiated electrical energy, an indicator to alert a user when activated, circuitry for determining when the sensed electrical energy meets a user adjustable threshold and activating the indicator when the sensed electrical energy meets the user adjustable threshold, and an adjustor for selecting the user adjustable threshold, wherein the elongate probe has a length of at least 2 feet;
adjusting the user adjustable threshold to a high sensitivity;
moving the elongate probe into the area to determine if electrical energy exists in the area;
if the indicator indicates the presence of electrical energy, adjusting the user adjustable threshold to a low sensitivity; and
moving the elongate probe into a portion of said area to determine if electrical energy exists in said portion.

8. The method of claim 7 further comprising:
if the indicator indicates the presence of electrical energy in the portion of the area, adjusting the user adjustable threshold to a lower sensitivity, said lower sensitivity lower than the low sensitivity; and
moving the elongate probe into a sub-portion of said portion of said area to determine if electrical energy exists in said sub-portion.

9. The method of claim 7 wherein the level of the lower sensitivity is selected to allow the elongate probe to sense electrical energy only in the portion of the area.

10. The method of claim 7 further comprising:
if the indicator does not indicate the presence of electrical energy in the portion of the area, moving the elongate probe through another portion of the area to determine if electrical energy exists in the another portion.
